(19) United States
(12) Patent Application Publication
(10) Pub. No.: US 2026/0320272 A1
(43) Pub. Date: Oct. 15, 2026

(54) PHALANX: A SCALABLE METHOD AND SYSTEM FOR VALIDATING THE INTEGRITY OF DIGITAL LOGIC DESIGNS USING STRUCTURAL AND BEHAVIORAL FINGERPRINTS

(71) Applicants: Roderick Lanard Ray, Cocoa, FL (US); Curtis Turner, JR., Lutz, FL (US)

(72) Inventors: Roderick Lanard Ray, Cocoa, FL (US); Curtis Turner, JR., Lutz, FL (US)

(21) Appl. No.: 19/411,742

(22) Filed: Dec. 8, 2025

Related U.S. Application Data
(60) Provisional application No. 63/730,959, filed on Dec. 11, 2024.

(51) Int. Cl. G06F 30/3323; G06N 7/01

(52) U.S. Cl. CPC G06F 30/3323; G06N 7/01

(57) ABSTRACT

A method and system are provided for determining whether internal logic of a digital block has been altered after integration into a larger design. A parser identifies signals, operations, and dependencies, and a directed acyclic graph is constructed to represent structural relationships. Structural data is combined with normalized Boolean relationships to generate a deterministic logic fingerprint reflecting structural and behavioral characteristics. After integration, the extraction process is repeated to generate a second fingerprint for comparison. Differences are analyzed to identify structural or behavioral changes, including added or removed logic, altered expressions, or modified signal dependencies. The method supports hierarchical designs by generating fingerprints for submodules and combining them into higher-level representations. The system may detect patterns indicative of obfuscation and can optionally incorporate dynamic monitoring of selected signals. The approach operates independently of naming or formatting variations and produces a stable representation when the underlying design is unchanged.

### CROSS-REFERENCE TO RELATED APPLICATIONS

This application claims priority to U.S. Provisional Patent Application No. 63/730,959, filed on Dec. 11, 2024. The entire contents of that provisional application are incorporated by reference.

### STATEMENT REGARDING FEDERAL FUNDING

No federal funding was used in the development of the invention.

### FIELD OF THE INVENTION

The invention relates to digital logic verification and more specifically to methods and systems for determining whether the internal logic of a circuit remains unchanged after integration. The invention generates a logic fingerprint that captures the structural and behavioral characteristics of a logic block so that changes can be detected reliably.

### BACKGROUND

Digital systems often incorporate logic blocks that originate from external or independent sources. These blocks may include licensed intellectual property, open-source components, or internal modules produced by separate design teams. When these blocks are integrated into a larger circuit, there is a risk that the internal logic may be altered. Changes may result from refactoring, optimization, synthesis transformations, or unintentional edits made during integration. In some situations, logic may also be modified intentionally in subtle ways that are difficult to detect.

Simulation verifies functional behavior only for the specific input sequences that are applied. A change inside a block may not be observable unless the simulation exercises the exact sequence that exposes the modification. Structural verification methods such as netlist comparison attempt to match graphs across two versions of a design. These methods become difficult to apply as designs grow in size because differences in formatting, naming, ordering, or tool-generated transformations can cause structures to appear different even when the logic is functionally the same.

Design teams require a reliable way to determine whether a logic block has remained unchanged after integration or transformation. They need a method that is stable across formatting differences, insensitive to naming variations, and independent of coding style. The method must remain consistent when the logic is unchanged and provide clear indications when the underlying behavior or structure has been modified. Current tools do not provide a stable and deterministic identity for a logic block that satisfies these requirements.

### SUMMARY

The invention provides a method and system that create a deterministic logic fingerprint for a logic block. The fingerprint represents both the internal structure and the logical behavior of the block in a reproducible format. After the logic block is integrated into a larger system, the fingerprint is generated again. Any difference between the two fingerprints indicates a change in the logic. The system identifies the type of change and the location of the modified structure or expression.

The method operates without simulation and does not depend on naming, formatting, or stylistic elements of the source description. Fingerprints remain stable when the logic is unchanged, and they change predictably when the underlying logic changes. The invention supports complex blocks through hierarchical fingerprinting and can detect a range of modifications including inserted logic, removed logic, altered Boolean expressions, obfuscation patterns, and signal rerouting.

### BRIEF DESCRIPTION OF THE DRAWINGS

FIG. 1 is a diagram that illustrates the overall Phalanx system architecture and the main components involved in generating and comparing fingerprints.

FIG. 2 is a diagram of a simple digital logic circuit used to demonstrate the basic methods applied during fingerprint extraction.

FIG. 3 is a diagram that shows a directed acyclic graph representation of a third-party logic block before integration.

FIG. 4 is a diagram that shows a directed acyclic graph representation of the same logic block after integration.

FIG. 5 is a diagram that compares the pre integration and post integration fingerprints and highlights the differences detected by the system.

FIG. 6 is a flow diagram that outlines the stages of the Phalanx fingerprinting process.

FIG. 7 is a diagram that illustrates the truth table combinations used during behavioral analysis.

FIG. 8 is a diagram that shows an isomorphic comparison between two logic blocks before and after integration.

FIG. 9 is a diagram that illustrates how hierarchical blocks are analyzed when the logic contains internal submodules.

FIG. 10 is a diagram that shows the dynamic monitoring process and optional use of runtime signals.

FIG. 11 is a diagram that presents the structure and role of test vectors used for optional dynamic verification.

FIG. 12A is a diagram that illustrates the clean reference fingerprint of the Ibex ALU.

FIG. 12B is a diagram that illustrates a modified version of the Ibex ALU fingerprint.

FIG. 12C is a diagram that compares the clean and modified Ibex ALU fingerprints and identifies the differences.

FIG. 13A is a diagram that illustrates the clean reference fingerprint of the Pico ALU.

FIG. 13B is a diagram that illustrates a modified version of the Pico ALU fingerprint.

FIG. 13C is a diagram that compares the clean and modified Pico ALU fingerprints and identifies the differences.

FIG. 14A is a diagram that illustrates the clean reference fingerprint of the Rocket ALU.

FIG. 14B is a diagram that illustrates a modified version of the Rocket ALU fingerprint.

FIG. 14C is a diagram that compares the clean and modified Rocket ALU fingerprints and identifies the differences.

### DETAILED DESCRIPTION OF THE FIGURES

The figures described in this section illustrate the structure, operation, and example applications of the Phalanx system. Each figure supports one or more aspects of the invention, including structural extraction, behavioral normalization, hierarchical analysis, dynamic monitoring, and fingerprint comparison.

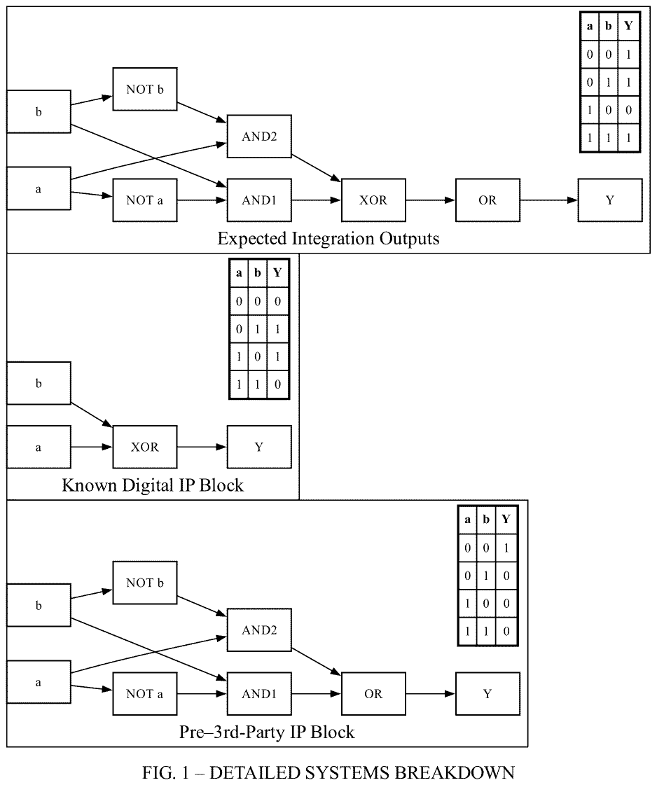

FIG. 1 illustrates the overall Phalanx system architecture. This includes the parser, the directed acyclic graph generator, the behavioral extraction module, the fingerprint generator, the comparison engine, and optional dynamic monitoring components. The diagram shows how information flows between stages during fingerprint generation and comparison.

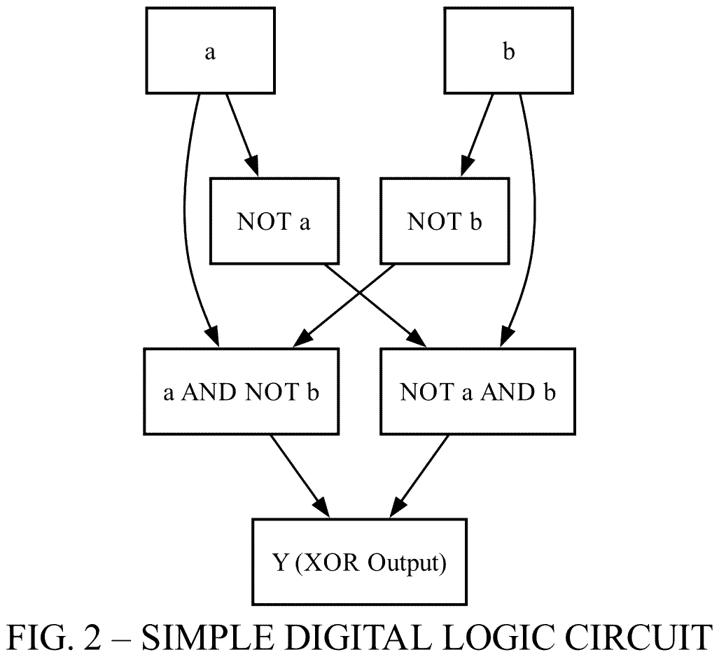

FIG. 2 shows a simple digital logic circuit used to demonstrate how nodes, edges, and Boolean relationships are represented inside the system. The figure highlights how the parser extracts assignments and how the DAG generator converts those assignments into a structural graph.

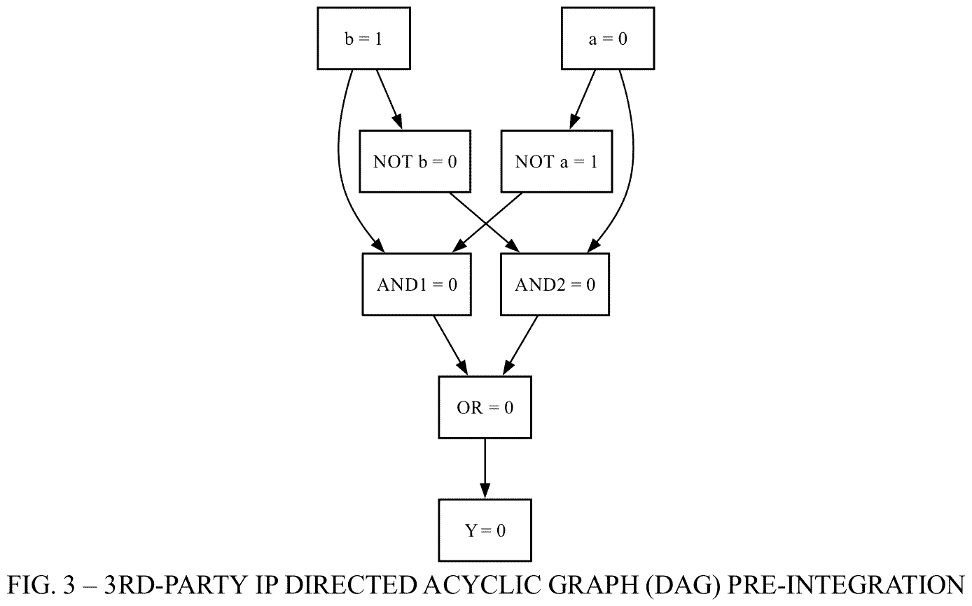

FIG. 3 shows a directed acyclic graph representation of a third-party logic block before integration. Nodes represent Boolean operations or expressions, and edges represent signal dependencies between operations. The figure demonstrates how structural identity is captured independent of naming or formatting.

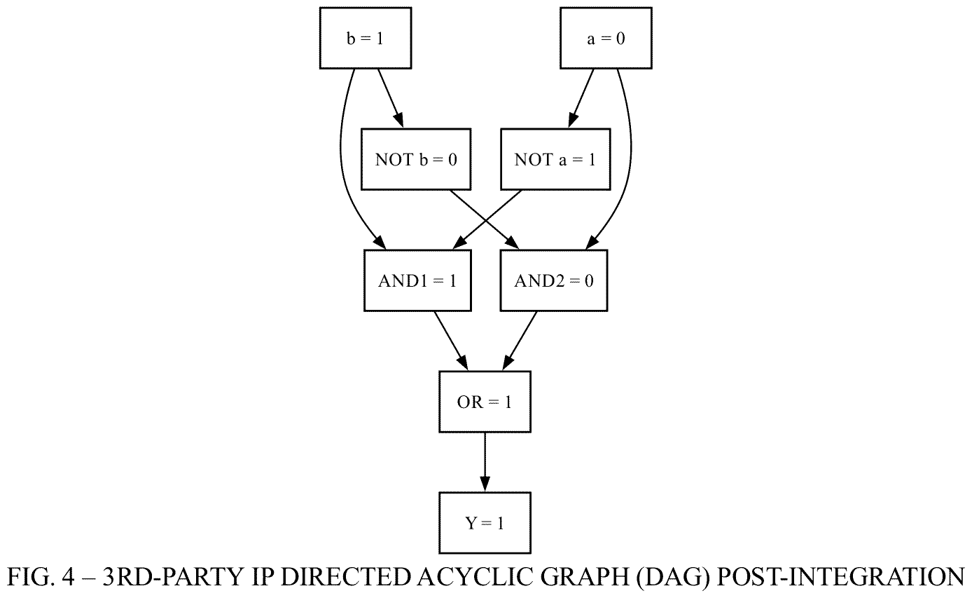

FIG. 4 shows a directed acyclic graph representation of the same third-party logic block after integration into a larger design. The figure highlights structural changes that may occur when logic is refactored, optimized, or unintentionally altered during the integration process.

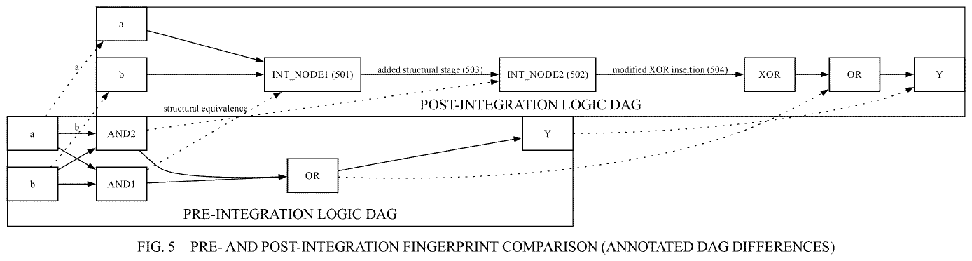

FIG. 5 shows a comparison between the pre-integration and post-integration fingerprints. Region 501 identifies portions of the logic that remain unchanged. Region 502 identifies portions that differ between the clean and integrated versions. This figure demonstrates how structural and behavioral mismatches are reported.

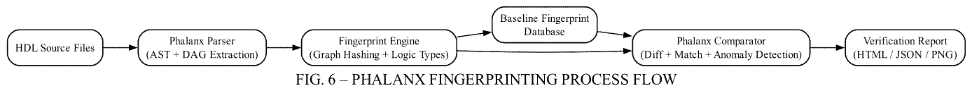

FIG. 6 illustrates the full fingerprinting process flow, including parsing, graph construction, Boolean normalization, behavioral extraction, fingerprint generation, hierarchical processing, and fingerprint comparison. The diagram shows the deterministic nature of the process.

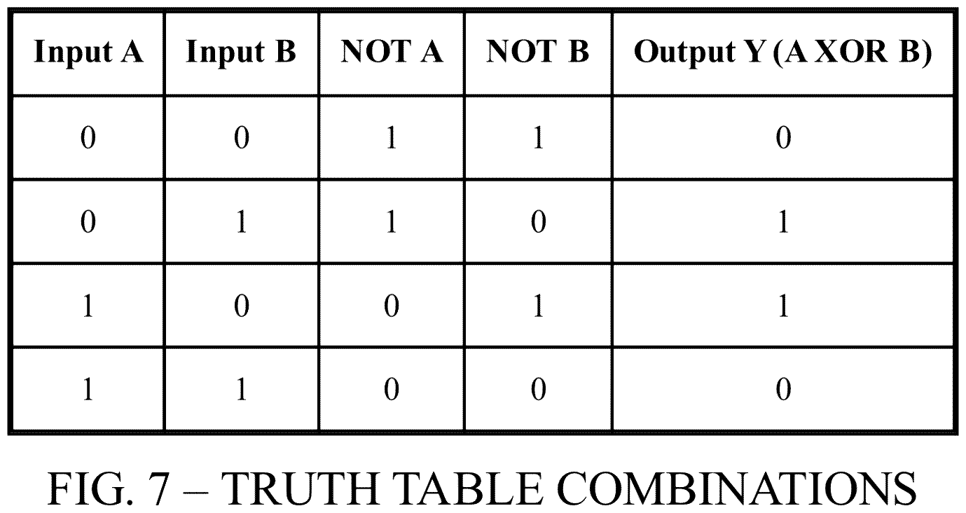

FIG. 7 presents representative truth table combinations used during behavioral extraction. These combinations establish how outputs depend on inputs and support the behavioral component of the logic fingerprint.

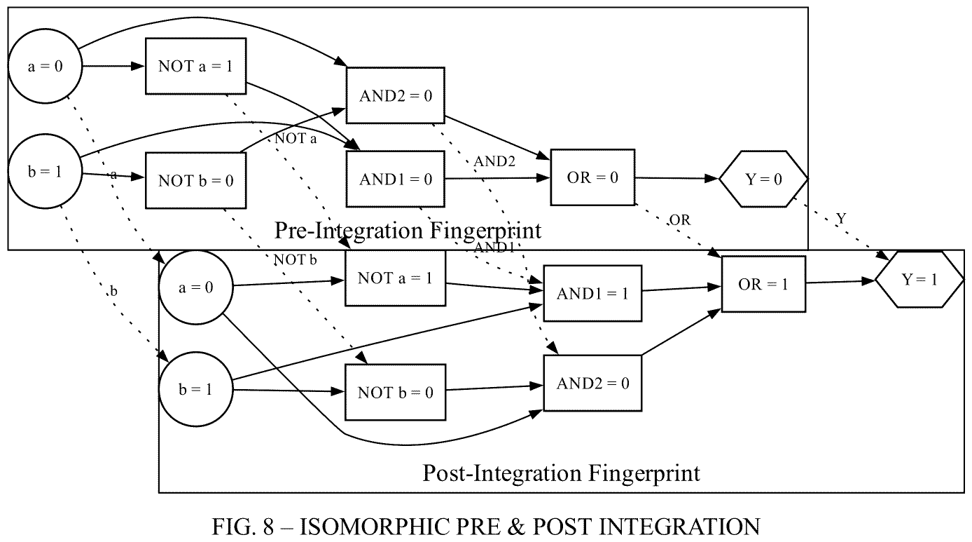

FIG. 8 illustrates an isomorphic comparison between two structurally similar logic blocks. The figure demonstrates that formatting changes, renaming, and ordering differences do not affect the resulting fingerprint when the underlying logic remains the same.

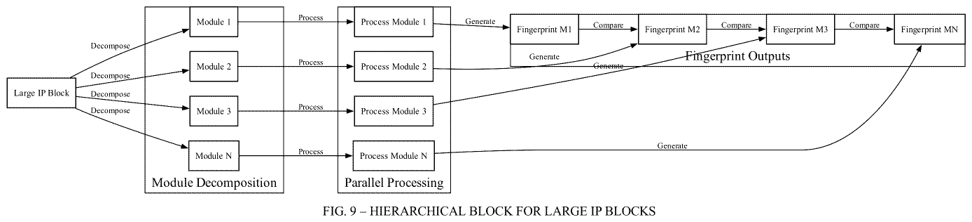

FIG. 9 illustrates hierarchical fingerprinting used when the logic block contains internal submodules. The figure shows how individual submodule fingerprints are combined to produce a consistent parent fingerprint while maintaining resolution at each level.

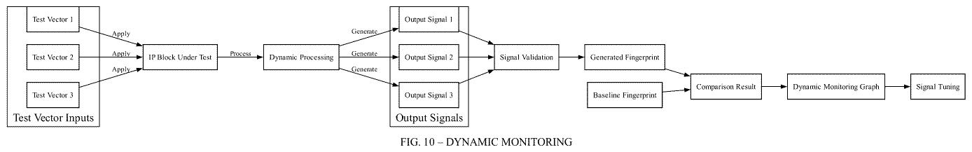

FIG. 10 shows the optional dynamic monitoring process. Internal signals are sampled during activation of the logic block, and the samples are used to confirm behavioral relationships. Dynamic sampling supplements, but does not replace, static structural and behavioral extraction.

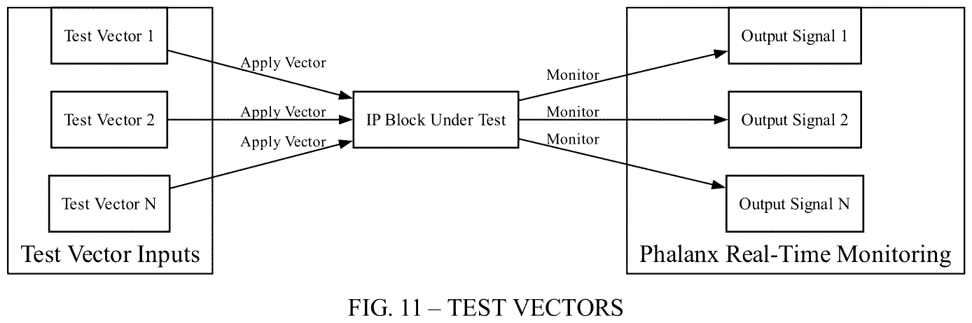

FIG. 11 illustrates the use of test vectors when behavioral sampling is enabled. The figure shows how input patterns are generated, applied, and interpreted during the behavioral component of the fingerprinting process.

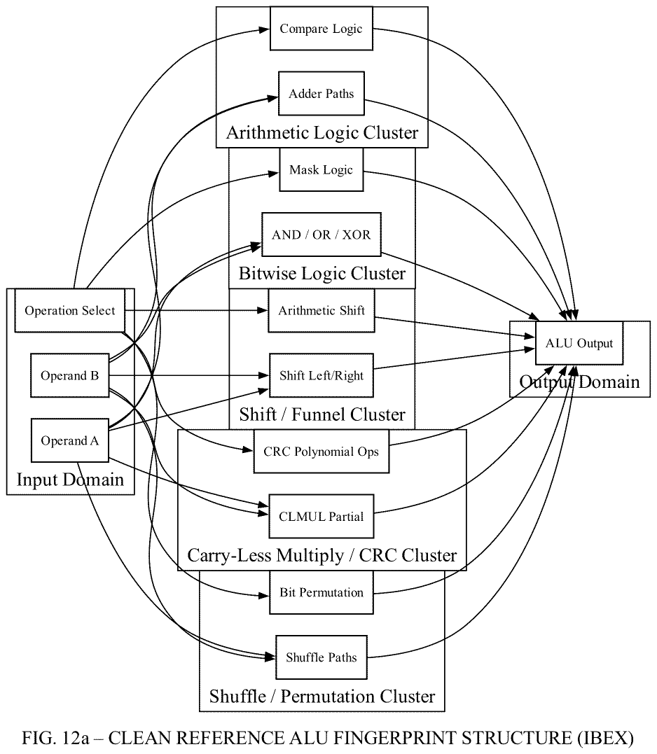

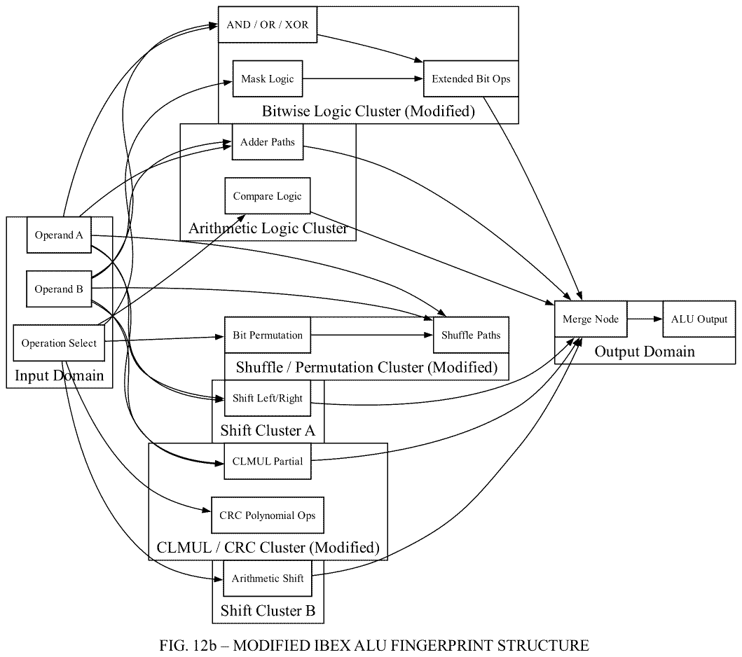

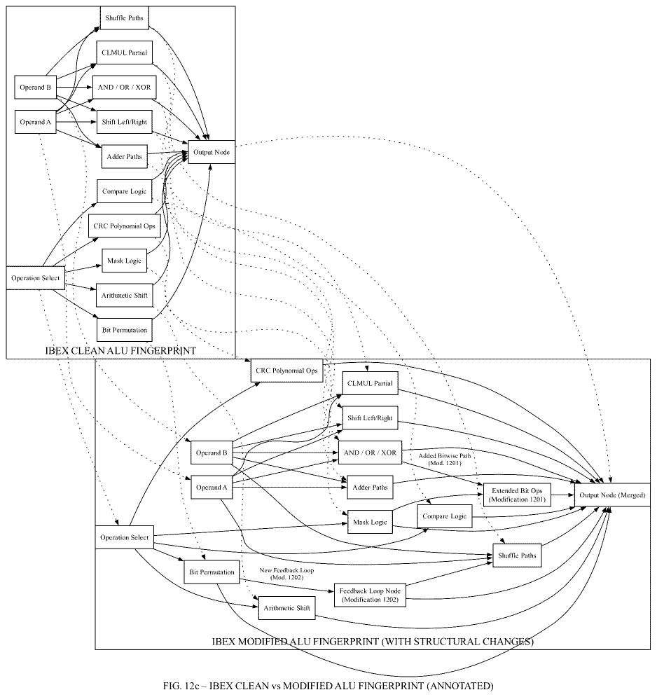

FIG. 12A shows the clean reference fingerprint of the Ibex RISC-V Core ALU. The figure presents the structural form of the ALU as extracted by the system.

FIG. 12B shows a modified version of the Ibex ALU fingerprint. Structural changes, behavioral changes, or both may appear depending on the nature of the modification.

FIG. 12C compares the clean and modified Ibex fingerprints. Region 1201 identifies logic that remains unchanged. Region 1202 identifies logic that differs, demonstrating how the system isolates the location and type of modification.

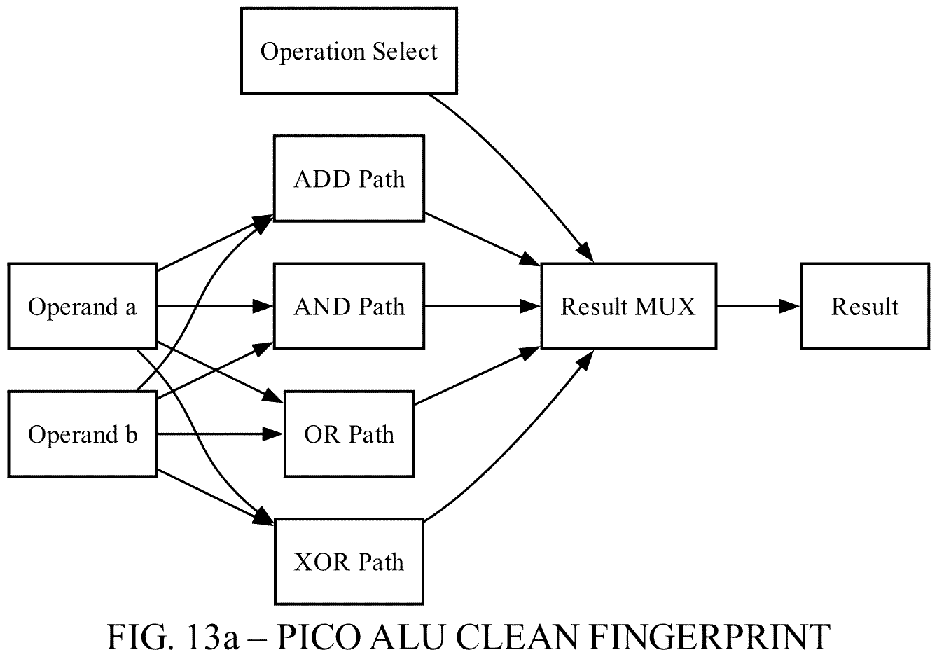

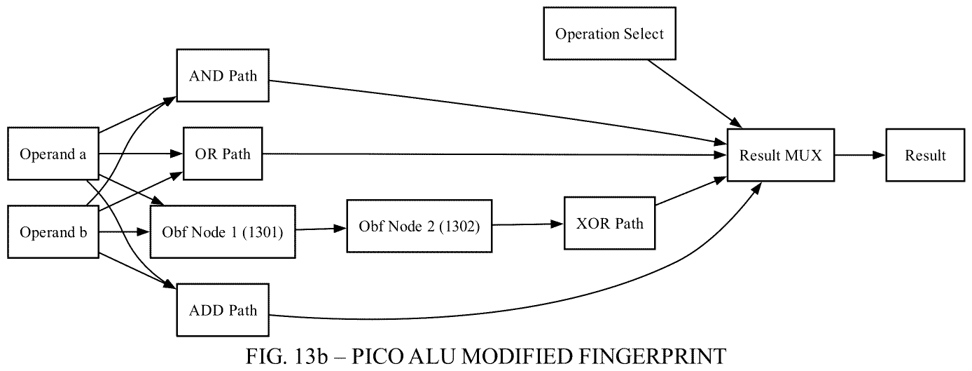

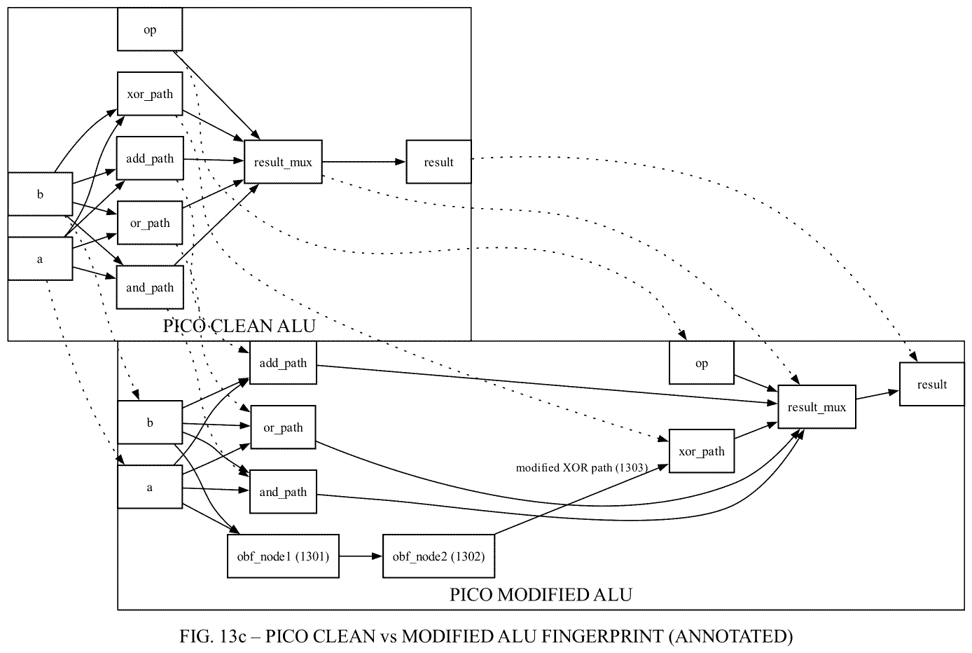

FIG. 13A shows the clean reference fingerprint of the PicoRV32 ALU.

FIG. 13B shows a modified version of the PicoRV32 ALU fingerprint.

FIG. 13C compares the clean and modified PicoRV32 fingerprints. Region 1301 identifies unchanged logic. Region 1302 identifies modified logic.

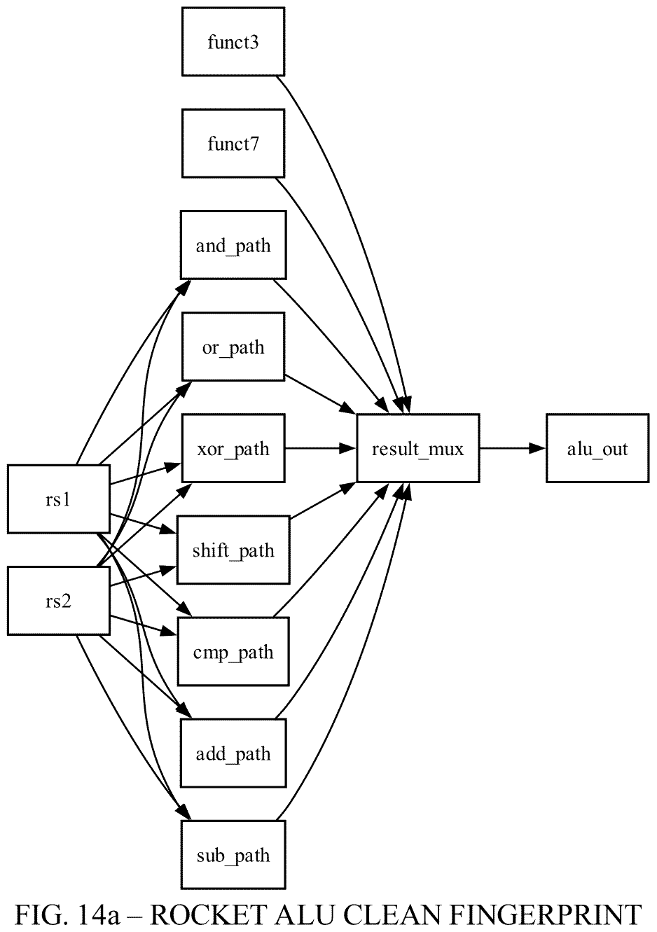

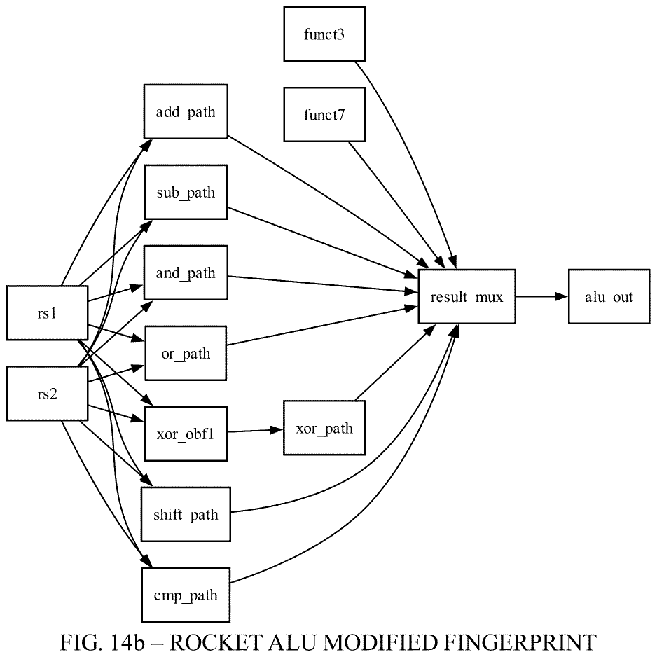

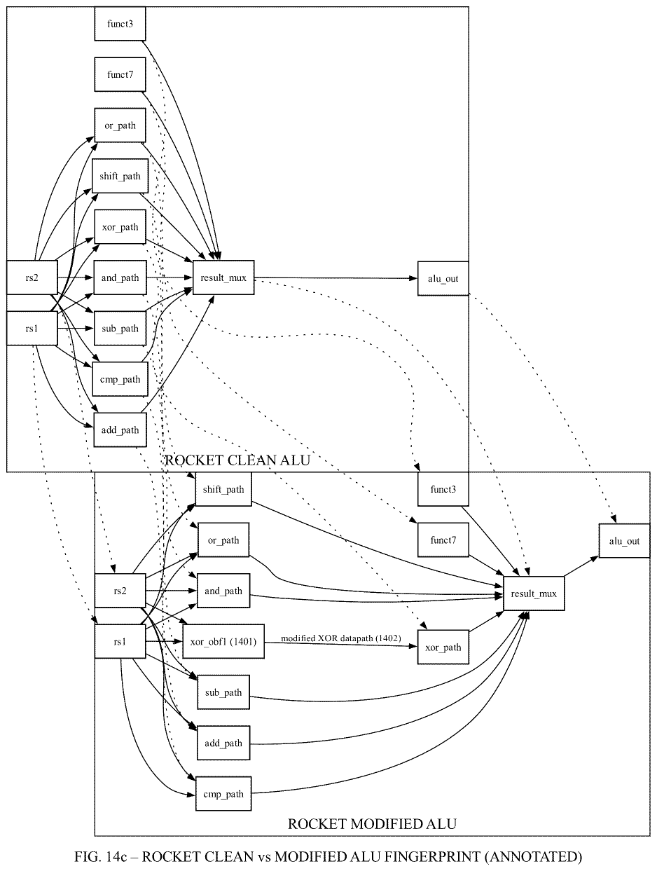

FIG. 14A shows the clean reference fingerprint of the Rocket Core ALU.

FIG. 14B shows a modified Rocket Core ALU fingerprint.

FIG. 14C compares the clean and modified Rocket fingerprints. Region 1401 identifies logic that remains unchanged. Region 1402 identifies logic that differs between the two versions.

### REFERENCE NUMERALS

The following reference numerals are used throughout the figures to identify structural and behavioral elements of the invention.

501 Region in which the structural characteristics of pre-integration and post-integration fingerprints match (FIG. 5).

502 Region in which the fingerprints differ, indicating a structural or behavioral modification (FIG. 5).

1201 Portion of the Ibex ALU fingerprint that remains unchanged between the clean and modified versions (FIG. 12C).

1202 Portion of the Ibex ALU fingerprint that contains modified logic (FIG. 12C).

1301 Portion of the PicoRV32 ALU fingerprint that remains unchanged between the clean and modified versions (FIG. 13C).

1302 Portion of the PicoRV32 ALU fingerprint that contains modified logic (FIG. 13C).

1401 Portion of the Rocket Core ALU fingerprint that remains unchanged between the clean and modified versions (FIG. 14C).

1402 Portion of the Rocket Core ALU fingerprint that contains modified logic (FIG. 14C).

### DETAILED DESCRIPTION OF THE INVENTION

The invention provides a method and system for determining whether the internal logic of a digital block has remained unchanged after integration into a larger design. The method generates a logic fingerprint that represents both the structural characteristics and the logical behavior of the block in a deterministic format. The fingerprint remains stable when the underlying logic is unchanged and produces measurable differences when the logic is modified. The following sections describe the definitions, components, and procedures used to generate the logic fingerprint and to detect changes in digital logic.

### Definitions

The following terms are used throughout this specification. These definitions are provided to ensure clarity and consistency when describing the operation of the system.

### Directed Acyclic Graph (DAG)

A directed graph that contains no cycles. In this invention, a DAG represents the structural organization of a logic block. Each node in the DAG corresponds to an operation, gate, or assignment, and each edge represents a data or control dependency between operations.

### Node

A functional element inside a logic block. A node may represent a Boolean operator, arithmetic operator, multiplexer, comparison operator, reduction operator, or assignment. Node types are used during structural and behavioral analysis.

### Edge

A directional connection between two nodes that identifies how signals flow from one operation to another. Edges define dependency relationships inside the DAG.

### Dependency

A relationship between two signals or operations where the value of one element is determined by another. Dependencies are extracted from RTL assignments and are used to construct the DAG and identify structural relationships inside the logic block.

### Logic Fingerprint

A deterministic and reproducible representation of a logic block that captures both structural and behavioral characteristics. The fingerprint remains stable across formatting differences, reordering, refactoring, and variable renaming. Any change in underlying logic produces a measurable change in the fingerprint.

### Structural Fingerprint

The portion of the logic fingerprint derived from the directed acyclic graph. It reflects the set of operations and the dependencies between them.

### Behavioral Fingerprint

The portion of the logic fingerprint derived from normalized Boolean expressions and optional truth table sampling. It represents how outputs respond to inputs.

### Behavioral Relationship

A description of how the outputs of a logic block depend on its inputs. Behavioral relationships are derived from Boolean or arithmetic expressions and are used to form the behavioral fingerprint.

### Normalization

A process that converts logic expressions into a consistent and canonical format. Normalization removes variability caused by formatting, ordering, or naming differences so that equivalent logic produces identical fingerprints even when written in different styles.

### Canonical Form

A standardized representation of a logic expression that follows a fixed set of formatting and ordering rules. Canonical forms ensure that logically equivalent expressions match during fingerprint comparison.

### Register Transfer Level (RTL)

A representation of digital logic that describes data flow between registers and the operations performed on that data. RTL expresses sequential and combinational behavior using constructs such as always blocks, assignments, operators, and conditional statements. In this invention, RTL serves as the source format from which structural and behavioral information is extracted to generate the logic fingerprint.

### Clean Version

The original or reference version of a logic block used as a baseline for comparison.

### Modified Version

A version of a logic block that contains intentional or unintentional changes. The modified version is evaluated by comparing its fingerprint to the clean version.

### Subgraph

A subset of nodes and edges inside the DAG that represents a specific region of logic. Subgraphs may correspond to operations, Boolean groupings, or functional units inside a block.

### Signal Path

The sequence of nodes and dependencies that a signal flows through inside the logic block. Changes to a signal path may indicate modifications to internal logic.

### Overview of the Phalanx Process

The system accepts a logic block written in register transfer level form. It extracts structural and behavioral information from the block to generate a logic fingerprint. The fingerprint is used as a reference during integration. After the block is integrated into a larger system, the process is repeated. The fingerprints are compared, and any difference indicates that the logic has changed.

The general process includes the following steps:

Parse the logic block and construct an internal representation.

Build a directed acyclic graph that captures the internal structure.

Normalize expressions to remove formatting and stylistic differences.

Extract behavioral information from Boolean relationships.

Generate a structural and behavioral fingerprint.

Compare fingerprints before and after integration.

Report differences and classify the type of change.

Each component of this process is described in detail in the sections below.

### Parsing and Internal Representation

The system converts the logic description into a uniform internal representation. Inputs, outputs, internal wires, registers, and assignments are identified. The parser records the operations used in each assignment and captures the dependencies between signals. The parser operates independently of formatting, ordering, or naming differences. Equivalent logic written in different styles produces the same internal representation.

### Graph Construction

A directed acyclic graph is built from the internal representation. Each node represents an operation or logic element. Edges represent the flow of data or control signals between nodes. The DAG captures the functional structure of the logic and forms the basis of the structural fingerprint.

The graph construction stage is designed to be stable. Formatting changes, code refactoring, or reordering of assignments do not alter the underlying DAG. The DAG changes only when the logic itself changes.

### Behavioral Extraction

Behavioral extraction identifies how outputs depend on inputs based on Boolean relationships. The system generates normalized Boolean expressions and may optionally perform truth table sampling. Normalization ensures that equivalent expressions produce the same behavioral fingerprint. This stage detects changes in logical behavior even when the structural presentation appears similar.

### Fingerprint Generation

A structural fingerprint is generated from the directed acyclic graph. A behavioral fingerprint is generated from normalized Boolean expressions and optional truth table evaluation. Together, these fingerprints provide a deterministic identity for the logic block.

If the logic remains unchanged, the fingerprints remain unchanged. If the logic is altered, the fingerprints differ. The system identifies the location and type of change.

### Integration Comparison

After integration, a new fingerprint is generated from the integrated version of the block. The system compares the clean fingerprint with the integrated fingerprint. Detected changes include added operations, removed operations, altered Boolean expressions, and modifications to signal dependencies. Results are reported in a structured format that identifies the type and location of each difference.

### Use of Open Source ALUs for Validation

The Ibex RISC V Core ALU, the PicoRV32 ALU, and the Rocket Core ALU are used as real-world examples to demonstrate the method. These designs are open source and distributed under permissive licenses. For testing, clean versions and modified versions of each ALU were created. The fingerprints extracted from the clean and modified versions illustrate the ability of the system to detect structural and behavioral differences. The invention does not claim any part of these ALUs. They are used only to demonstrate the operation of the method.

### Mismatch Classification

The system compares the logic fingerprint generated from the clean version of a block with the fingerprint generated after integration. When differences are present, the system classifies the change. The classification process identifies whether logic has been added, removed, or altered. The system evaluates differences in node count, edge structure, Boolean expression form, or signal dependencies. These differences are interpreted to determine the type of modification that occurred inside the block.

Added logic is identified when new nodes or new signal paths appear in the directed acyclic graph. Removed logic is identified when nodes or paths from the clean fingerprint are missing in the integrated fingerprint. Altered logic is identified when expressions, operators, or dependency structures differ between versions. Classification allows the user to understand not only that a change occurred, but also the nature of the change.

### Hierarchical Fingerprinting

Large designs often contain submodules or nested logic blocks. The system supports hierarchical fingerprinting to manage these structures. Each submodule receives its own logic fingerprint. The fingerprints of lower-level blocks are combined to produce a fingerprint for the parent block. This approach allows the system to scale to large and complex circuits without losing resolution.

If a submodule is modified, its fingerprint changes. The parent module fingerprint reflects that change. This method allows the system to identify changes at any level of hierarchy and to isolate the location where the modification occurred. Hierarchical fingerprinting maintains consistency regardless of module size and supports both flat and nested architectures.

### Obfuscation Pattern Detection

Some modifications involve intentional obfuscation. These patterns attempt to conceal structural changes by inserting additional logic, rewriting Boolean expressions, or rearranging signals in ways that do not change functionality. The system identifies potential obfuscation by analyzing unusual graph structures, redundant logic, altered dependency paths, or irregular Boolean forms.

The system flags conditions such as XOR or XNOR chains, rearranged multiplexing structures, signal masking, and inserted constant logic. These patterns often indicate attempts to hide logic modifications. The system reports these indicators along with the fingerprint mismatch results. The identification of obfuscation patterns provides an additional layer of insight beyond simple structural comparison.

### Dynamic Monitoring

In addition to static comparison, the system supports optional dynamic monitoring of signal behavior. Dynamic monitoring samples internal signals to observe how outputs respond to input variations. Sampling does not replace static comparison. It provides supplemental data that can highlight behavioral changes that may not be obvious from structure alone. Results from dynamic monitoring are integrated into the behavioral fingerprint.

Dynamic monitoring is especially useful in cases where structural modifications produce the same logic function but with altered paths or expressions. Behavioral sampling confirms whether the internal changes affect overall behavior. Dynamic and static results together produce a complete view of the logic block.

### Example Workflow for Logic Block Verification

The following example describes how the system is used in a typical design environment. A design team verifies a block by generating a clean logic fingerprint before integration. After the block is integrated into a larger design, the team generates a second fingerprint from the integrated version. The fingerprints are compared. If the fingerprints match, the block has remained unchanged. If the fingerprints differ, the team examines the mismatch report to understand the type and location of the modification.

This workflow applies to small modules and large hierarchical blocks. It does not require simulation, naming consistency, or format alignment between versions. The system provides a deterministic way to confirm whether the block's internal logic has remained intact through the design process.

### Application to Real World ALUs

The method was evaluated using three real world open source ALUs. These include the Ibex RISC V Core ALU, the PicoRV32 ALU, and the Rocket Core ALU. Clean versions were prepared for each ALU. Modified versions were created by altering Boolean expressions, changing operator structure, or inserting additional logic. For each ALU, the system generated fingerprints for both versions and compared them.

In all cases, the system produced distinct fingerprints for clean and modified versions. The mismatch classification identified the type of modification that occurred. The hierarchical fingerprinting mechanism captured changes in larger structures as needed. These results confirm that the method works across different architectures and coding styles. The invention does not claim any part of these ALUs. They are used only to demonstrate the operation of the method.

### System Flow and End to End Operation

The overall operation of the system follows a structured sequence. The user begins by providing the clean version of a logic block. The system parses the block, constructs the directed acyclic graph, normalizes Boolean expressions, and generates the logic fingerprint. This fingerprint serves as the reference identity for the block.

After the block is integrated into a larger circuit, the user supplies the integrated version to the system. The system repeats the same extraction and fingerprinting steps. The two fingerprints are then compared. The comparison identifies changes in structure or behavior and produces a report that describes the type and location of the modifications.

The system does not require matching variable names, formatting, comments, or code structure between the two versions. All structural and behavioral information is extracted from the functional content of the logic. Differences detected in the fingerprint directly reflect differences in the underlying logic.

### Figure Integration and System Components

The invention is illustrated through a series of figures. These figures describe the components, workflows, and example situations in which the method is applied.

FIG. 1 presents an overview of the system. It shows the primary components of the process including the parser, the directed acyclic graph generator, the behavioral extractor, the fingerprint generator, and the comparison module.

FIG. 2 shows a simple digital logic circuit used to demonstrate how nodes, edges, and Boolean relationships are represented inside the system.

FIG. 3 and FIG. 4 illustrate a third-party logic block before and after integration. These figures show how structural dependencies appear in the graph representation.

FIG. 5 presents an annotated comparison of pre integration and post integration fingerprints. The figure highlights structural and behavioral changes that result from modifications inside the block.

FIG. 6 shows the flow of the fingerprinting process from parsing through comparison.

FIG. 7 shows example truth table combinations used in behavioral extraction.

FIG. 8 shows an isomorphic match between a clean block and a modified block where formatting changes do not alter the logic fingerprint.

FIG. 9 illustrates hierarchical fingerprinting for a large block where submodules are fingerprinted independently.

FIG. 10 provides an overview of optional dynamic monitoring and how sampled behavior may be used to support comparison.

FIG. 11 illustrates test vector generation in cases where behavioral exploration is applied to confirm functional relationships.

FIG. 12A through FIG. 12C show the clean, modified, and annotated comparison fingerprints for the Ibex RISC V Core ALU.

FIG. 13A through FIG. 13C show the same three states for the PicoRV32 ALU.

FIG. 14A through FIG. 14C show the corresponding states for the Rocket Core ALU.

These figures show how the method applies consistently across logic written in different styles, originating from different projects, and structured through different microarchitectural conventions.

### End to End Verification Example

To demonstrate the method, a designer begins with a clean version of the logic block. The system generates its logic fingerprint. The block is then integrated into a larger project. After integration, the system analyzes the integrated version and generates a second fingerprint. The two fingerprints are compared. If they are identical, the internal logic has remained unchanged.

If the fingerprints differ, the system examines structural and behavioral mismatches and identifies the reason for the difference. Added nodes, removed nodes, altered expressions, or changed dependencies appear in the comparison result. If the system detects patterns that indicate obfuscation, it reports those indicators along with the fingerprint differences.

This process provides assurance that logic blocks have not been altered in ways that escape traditional simulation or structural comparison tools. The method scales from small modules to complex hierarchical blocks and applies to clean room designs, licensed intellectual property, and open-source logic.

1. A method for determining whether a logic block has been altered after integration into a digital system, the method comprising: receiving a clean version of the logic block; generating a first logic fingerprint that characterizes structural and behavioral features of the clean version; receiving an integrated version of the logic block; generating a second logic fingerprint from the integrated version; and determining whether the logic block has changed by comparing the first logic fingerprint with the second logic fingerprint.

2. The method of claim 1, wherein generating each logic fingerprint comprises constructing a directed acyclic graph that represents internal signal dependencies of the logic block.

3. The method of claim 1, wherein generating each logic fingerprint comprises extracting normalized Boolean expressions from the logic block.

4. The method of claim 1, wherein comparing the logic fingerprints comprises identifying additions, deletions, or modifications of internal logic.

5. The method of claim 1, wherein determining whether the logic block has changed further comprises identifying a type of modification selected from the group consisting of structural changes, behavioral changes, and obfuscation-related changes.

6. The method of claim 1, wherein generating each logic fingerprint further comprises performing hierarchical fingerprinting in which submodules of the logic block are fingerprinted individually before forming a parent fingerprint.

7. The method of claim 1, wherein generating each logic fingerprint further comprises performing optional dynamic sampling to observe behavior of internal signals.

8. The method of claim 1, wherein comparing the first and second logic fingerprints comprises determining that the logic block remains unchanged when the logic fingerprints match.

9. The method of claim 1, wherein comparing the first and second logic fingerprints comprises determining that the logic block differs when the logic fingerprints do not match.

10. A system for determining whether a logic block has been altered after integration into a digital system, the system comprising: a parser configured to receive a clean version and an integrated version of the logic block; a structural extractor configured to construct a directed acyclic graph for each version; a behavioral extractor configured to normalize Boolean expressions for each version; a fingerprint generator configured to generate logic fingerprints from the structural and behavioral information; and a comparison module configured to determine whether the logic block has changed by comparing the logic fingerprints.

11. The system of claim 10, wherein the structural extractor is further configured to identify changes in node count or edge structure between fingerprints.

12. The system of claim 10, wherein the behavioral extractor is further configured to identify modifications in Boolean expressions between fingerprints.

13. The system of claim 10, wherein the comparison module is further configured to classify differences as structural changes, behavioral changes, or obfuscation-related changes.

14. The system of claim 10, wherein the fingerprint generator is further configured to perform hierarchical fingerprinting for logic blocks containing submodules.

15. The system of claim 10, wherein the behavioral extractor is further configured to perform optional dynamic sampling of internal signals.

16. A non-transitory computer-readable medium storing instructions that, when executed by one or more processors, cause the processors to perform the method of claim 1.

17. A method for validating integrity of a logic block across multiple stages of a digital design process, the method comprising: generating a logic fingerprint for the logic block at a first stage; generating a subsequent logic fingerprint for the logic block at a later stage; and determining whether the logic block has changed by comparing the logic fingerprints.

18. The method of claim 17, wherein determining whether the logic block has changed further comprises identifying a modification selected from the group consisting of structural changes, behavioral changes, hierarchy-level changes, and obfuscation patterns.
